(19) United States
(12) Patent Application Publication
(10) Pub. No.: US 2024/0107670 A1
(43) Pub. Date: Mar. 28, 2024

(54) ELECTRONIC COMPONENT, DISPLAY APPARATUS, AND IMAGING APPARATUS

(71) Applicant: CANON KABUSHIKI KAISHA, Tokyo (JP)

(72) Inventor: JUN TSUKANO, Tokyo (JP)

(21) Appl. No.: 18/475,060

(22) Filed: Sep. 26, 2023

(30) Foreign Application Priority Data
Sep. 28, 2022 (JP) 2022-155186

(51) Int. Cl. H05K 1/14; H01R 12/62; H01R 12/65; H04N 23/53; H05K 3/36

(52) U.S. Cl. CPC H05K 1/14; H01R 12/62; H01R 12/65; H04N 23/53; H05K 3/361; H01R 4/70; H05K 2201/041; H05K 2201/09045

(57) ABSTRACT

An electronic component includes first and second electrodes, first and second substrates having first and second principal surfaces, respectively, and a connection member to connect the first and second electrodes, wherein the first and second electrodes are arranged on the first and second principal surfaces, respectively, a height of the connection member is greater than those of the first and second electrodes in the direction perpendicular to the first principal surface, a distance between a portion of the first principal surface not in contact with the first electrode and a portion of the second principal surface not in contact with the second electrode is shorter than a distance between a portion of the first principal surface in contact with the first electrode and a portion of the second principal surface in contact with the second electrode, and an intermediary body is arranged between the second electrode and the connection member.

### BACKGROUND OF THE INVENTION

### Field of the Disclosure

The present disclosure relates to an electronic component, a display apparatus including the electronic component, and an imaging apparatus including the electronic component.

### Description of the Related Art

An electronic component arranged in an imaging apparatus, a display apparatus, or the like includes an electronic substrate on which an electronic element is arranged, and a circuit substrate for supplying power to the electronic substrate from the outside. To prevent entry of moisture and foreign substances from the outside, the electronic substrate and the circuit substrate are covered with a package member in some cases.

The electronic substrate includes an element region in which the electronic element is formed and a peripheral region that is arranged on an outer edge side of the element region. An external connection terminal is arranged in the peripheral region, and the external connection terminal is electrically connected to a circuit substrate such as a flexible printed circuit (FPC) substrate and an epoxy substrate including a glass cloth. Examples of a method of electrical connection include a method of using an anisotropically conductive film, an anisotropically conductive paste, or a connection member (bump). The anisotropically conductive film is a film material containing conductive particles. The anisotropically conductive paste is a liquid material containing conductive particles.

International Publication No. 2016/194370 describes that, to prevent a fracture of a connection portion between a connection member and an electrode, the perimeter of the connection member is reinforced with a resin.

In a structure described in International Publication No. 2016/194370, however, a volume between adjacent connection members is large. A filling member such as a resin and air is put between the adjacent connection members. The filling member tends to thermally expand with increase of an environmental temperature. Thus, the filling member may cause the fracture of the connection portion between the connection member and the electrode under a high temperature.

### SUMMARY OF THE INVENTION

Aspects of the present disclosure provide an electronic component that is capable of preventing a fracture of a connection portion between a connection member and an electrode under a high temperature.

According to an aspect of the present disclosure, an electronic component includes a first electrode, a second electrode, a first substrate having a first principal surface, a second substrate having a second principal surface, and a connection member configured to connect the first electrode and the second electrode, wherein the first electrode and the second electrode are arranged on the first principal surface and the second principal surface, respectively, wherein a height of the connection member in a perpendicular direction of the first principal surface is greater than a height of each of the first electrode and the second electrode in the perpendicular direction of the first principal surface, wherein a distance between a portion of the first principal surface that is not in contact with the first electrode and a portion of the second principal surface that is not in contact with the second electrode is shorter than a distance between a portion of the first principal surface that is in contact with the first electrode and a portion of the second principal surface that is in contact with the second electrode, and wherein an intermediary body is arranged between the second electrode and the connection member.

Further features of the present disclosure will become apparent from the following description of embodiments with reference to the attached drawings.

### BRIEF DESCRIPTION OF THE DRAWINGS

FIG. 1 is a perspective view of an electronic component according to a first embodiment of the present disclosure.

FIG. 2A is a top view according to the first embodiment of the present disclosure. FIG. 2B is a schematic cross-sectional diagram according to the first embodiment of the present disclosure. FIG. 2C is a schematic cross-sectional diagram along an F line in FIG. 2A according to the present disclosure.

FIGS. 3A to 3D are diagrams for describing a manufacturing method for manufacturing the electronic component according to the first embodiment of the present disclosure.

FIG. 4 is a schematic cross-sectional diagram according to a second embodiment of the present disclosure.

FIGS. 5A and 5B are schematic cross-sectional diagrams according to a third embodiment of the present disclosure.

FIGS. 6A and 6B are schematic cross-sectional diagrams according to a fourth embodiment of the present disclosure.

FIG. 7 is a schematic diagram illustrating an example of a display apparatus according to an embodiment of the present disclosure.

FIG. 8A is a schematic diagram illustrating an example of an imaging apparatus according to an embodiment of the present disclosure. FIG. 8B is a schematic diagram illustrating an example of an electronic apparatus according to an embodiment of the present disclosure.

FIG. 9A is a schematic diagram illustrating an example of a display apparatus according to an embodiment of the present disclosure. FIG. 9B is a schematic diagram illustrating an example of a bendable display apparatus.

FIG. 10A is a schematic diagram illustrating an example of an illuminating apparatus according to an embodiment of the present disclosure. FIG. 10B is a schematic diagram illustrating an example of an automobile including a vehicle lighting fixture according to an embodiment of the present disclosure.

FIG. 11A is a schematic diagram illustrating an example of a wearable device according to an embodiment of the present disclosure. FIG. 11B is a schematic diagram illustrating an example of a wearable device according to an embodiment of the present disclosure and illustrating a mode including an imaging apparatus.

### DESCRIPTION OF THE EMBODIMENTS

Exemplary embodiments of the present disclosure will be described in detail below with reference to the accompanying drawings. The embodiments do not limit the claimed disclosure. While a plurality of features is described in the embodiments, not all of the features are necessarily essential to the present disclosure, and the features may be freely combined. In the accompanying drawings, an identical or similar component is denoted by an identical reference number, and an overlapping description is omitted.

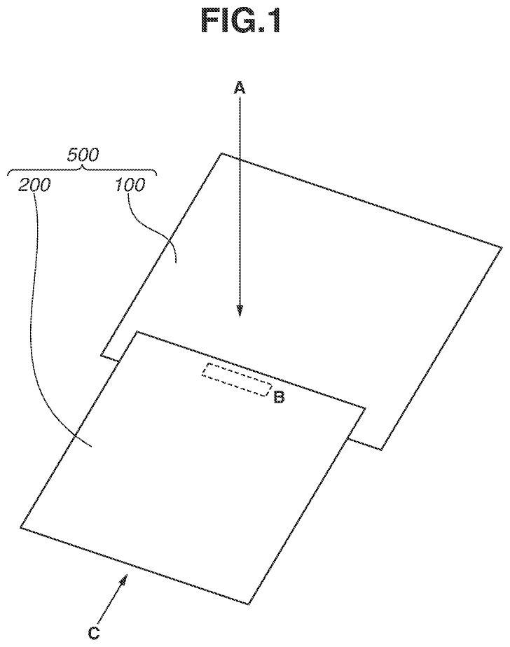

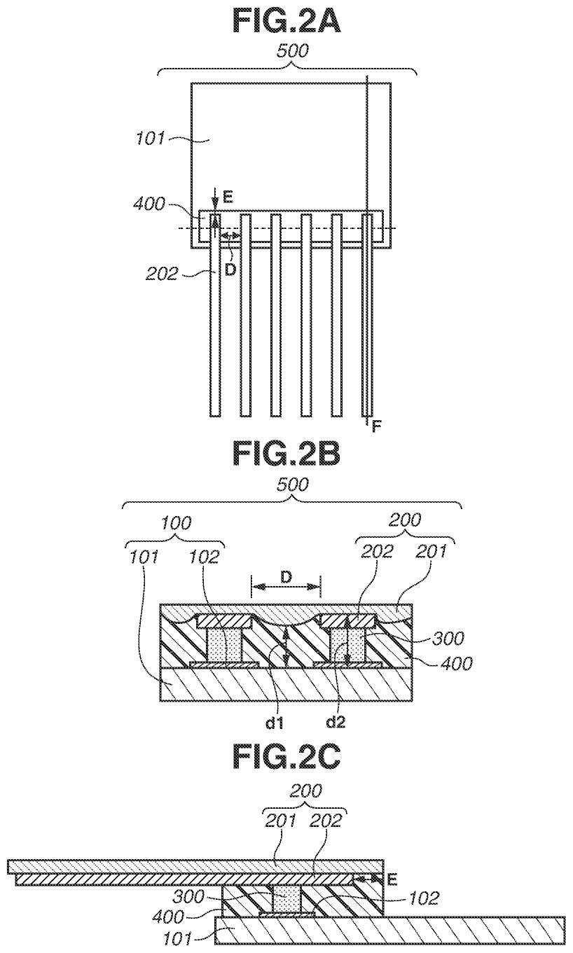

An electronic component 500 according to a first embodiment is to be described with reference to FIGS. 1, 2A, and 2B. FIG. 1 is a perspective view illustrating a structure of the electronic component 500 according to the first embodiment. FIG. 2A is a plan view of the electronic component 500 when viewed from a direction of A illustrated in FIG. 1, but illustration of a second substrate 201 is omitted for convenience sake. FIG. 2B is a cross-sectional diagram of an electrode connection portion (B in FIG. 1) when viewed from a direction of C illustrated in FIG. 1. In FIG. 2B, illustration of an element region is omitted, and will be described below. The electronic component 500 can include a first structure (electronic substrate) 100, a second structure (circuit substrate) 200, a connection member 300, and a filling member. The filling member may be air, a resin, or the like. In the embodiments, a description is given taking a resin member 400 as an example.

A first structure 100 can include a first substrate 101 composed of a substrate material such as silicon and glass, and a first electrode 102 arranged on a first principal surface of the first substrate 101. The first principal surface of the first substrate 101 can include an element region in which an electronic element is arranged and a peripheral region arranged between the element region and an edge of the first substrate 101, and the first electrode 102 can be arranged in the peripheral region. The first principal surface of the first substrate 101 may or may not be covered with another layer. When the first principal surface of the first substrate 101 is covered with the other layer, the other layer may be an insulation layer. Specifically, the insulation layer can include an oxide layer, a nitride layer, an oxynitride layer, and a resin layer. A second structure 200 can include the second substrate 201 and a second electrode 202 arranged on a second principal surface of the second substrate 201. The second electrode 202 is arranged so as to face the first electrode 102. Thus, the second principal surface is also arranged so as to face the first principal surface. Typically, the first substrate 101 includes a plurality of first electrodes 102 arranged on the first principal surface, and the second substrate 201 includes a plurality of second electrodes 202 arranged on the second principal surface. In this case, a corresponding one of the plurality of second electrodes 202 faces each of the plurality of first electrodes 102. The connection member 300 is arranged so as to electrically connect the first electrode 102 of the first structure 100 and the second electrode 202 of the second structure 200. A height of the connection member 300 in a direction perpendicular to the first principal surface may be greater than a height of each of the first electrode 102 and the second electrode 202 in the direction perpendicular to the first principal surface. The resin member 400 is an adhesive such as a thermosetting resin, an ultraviolet (UV)-curable resin, and a UV- and thermo-curable resin, and is arranged between the first substrate 101 and the second substrate 201 so as to surround the perimeter of the connection member 300.

The second structure 200 is, for example, a flexible wiring second surface, and is, more specifically, a flexible film that is made of polyimide or the like and on which a wiring pattern is formed. Alternatively, the second structure 200 may be a rigid flexible wiring substrate, which is a complex of a flexible film and a rigid substrate. The second structure 200 can be configured to supply power to the first structure 100 from an external device. The second structure 200 can have a function of inputting a signal from an external device to the first structure 100, and a function of transmitting or outputting a signal from the first structure 100 to the external device.

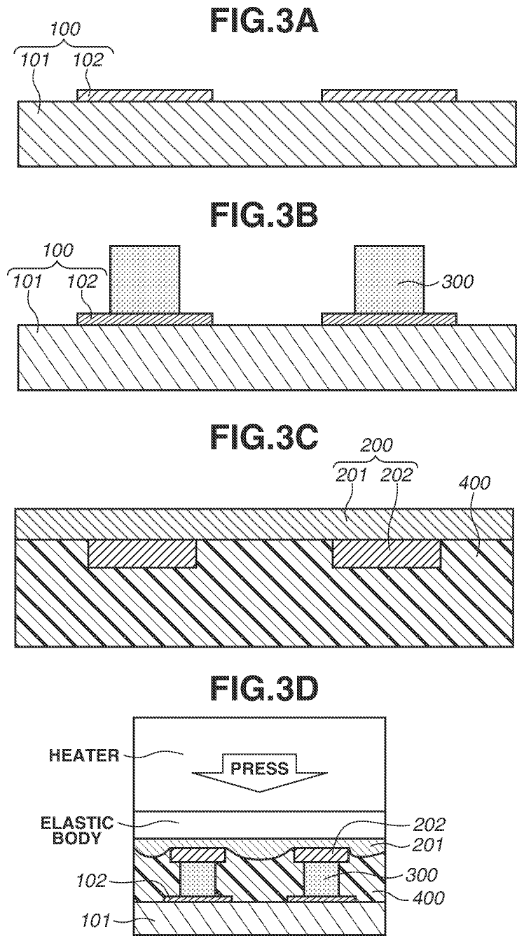

A manufacturing method for manufacturing the electronic component 500 according to the first embodiment is to be described with reference to FIGS. 3A to 3D. First, as exemplified in FIG. 3A, the first structure 100 is prepared in which the first electrode 102 is arranged on the first principal surface of the first substrate 101 made of silicon, glass, or the like.

As exemplified in FIG. 3B, the connection member 300 is formed on the first electrode 102.

For example, the connection member 300 may be formed by a wire bonding method or a plating method. Particularly, in a case where the connection member 300 is formed by the wire bonding method, the connection member 300 may be a stud bump. In a case where the connection member 300 is formed by the plating method, the connection member 300 is only required to be formed by an electrolytic plating method or an electroless plating method. In a case where the connection member 300 is formed by the plating method, a plating bath (plating liquid) may contain gold, silver, copper, or nickel. A material of the connection member 300 may be gold, silver, copper, or the like. The connection member 300 is formed on the first electrode 102, but may be formed on the second electrode 202.

The second structure 200 is prepared in which the second electrode 202 is arranged on the second principal surface of the second substrate 201 such as the flexible wiring substrate or the like. As exemplified in FIG. 3C, a resin member 400 is arranged on the second principal surface of the second structure 200. The resin member 400 is arranged in the second structure 200, but may be formed in the first structure 100.

As exemplified in FIG. 3D, the first structure 100 and the second structure 200 are arranged so that the connection member 300 connects the first electrode 102 and the second electrode 202. Thereafter, the second structure 200 is pressed and heated with heat and pressure, whereby the resin member 400 is cured while the connection member 300 and the second electrode 202 are brought into contact with each other. At this time, an elastic body may be arranged between a heater and the electronic component 500. The elastic body may be a Teflon (registered trademark) sheet, a rubber sheet, or the like. The second structure 200 is pressed and heated, but the first structure 100 may be pressed and heated or the first structure 100 and the second structure 200 may be pressed and heated.

According to the above-mentioned manufacturing method, in the electronic component 500 according to the present disclosure, a distance between a portion of the first principal surface that is not in contact with the first electrode 102 and a portion of the second principal surface that is not in contact with the second electrode 202 can be shorter than a distance between a portion of the first principal surface that is in contact with the first electrode 102 and a portion of the second principal surface that is in contact with the second electrode 202. In other words, d1 can be made shorter than d2 in FIG. 2B. Because the resin member 400 tends to expand more than a metal of the first electrode 102/the second electrode 202 under a high-temperature environment, there is a case where the resin member 400 causes a fracture of the connection portion between the first electrode 102/the second electrode 202 and the connection member 300. The electronic component 500 according to the present disclosure has the above-mentioned structure, and thereby an increase in volume of the resin member 400 arranged between the first substrate 101 and the second substrate 201 can be prevented. As a result, in the electronic component 500, an increase in amount of thermal expansion of the resin member 400 can be prevented under a high temperature environment, and thereby the fracture of the connection portion between the first electrode 102/the second electrode 202 and the connection member 300 can be prevented. In other words, the electronic component 500 can increase reliability of the connection portion between the first electrode 102/the second electrode 202 and the connection member 300. The electronic component 500 according to the present disclosure can obtain an advantageous effect, which is similar to that obtained between the second electrodes 202 (a D region in FIG. 2B), also between the second electrode 202 and the first substrate 101 (an E region in FIGS. 2A and 2C). In other words, in the electronic component 500, the increase in volume of the resin member 400 in the E region illustrated in FIGS. 2A and 2C can be prevented. Hence, in the electronic component 500, the fracture of the connection portion between the first electrode 102/the second electrode 202 and the connection member 300 can be further prevented. FIG. 2C is a schematic cross-sectional diagram when viewed from a direction of F illustrated in FIG. 2A.

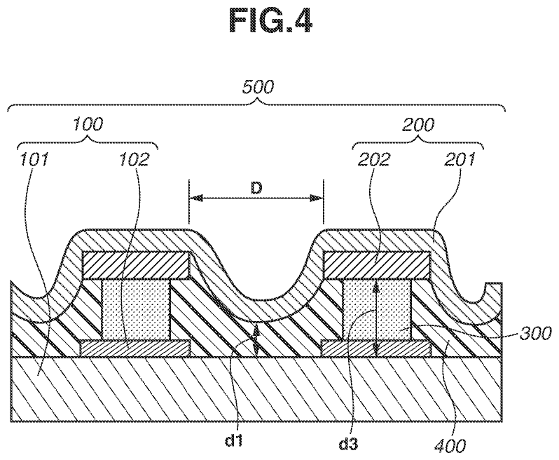

An electronic component 500 according to a second embodiment is to be described with reference to FIG. 4.

Assume that a surface that is in contact with the second electrode 202 and the connection member 300 is a third principal surface. The second electrode 202 and the connection member 300 may be in direct contact with each other, or may be in contact with each other via an intermediary body. The intermediary body will be described in detail below in a third embodiment. The second embodiment is different from the first embodiment described with reference to FIG. 2B in that a distance between the portion of the first principal surface that is not in contact with the first electrode 102 and the portion of the second principal surface that is not in contact with the second electrode 202 is shorter than a distance between the third principal surface and the portion of the first principal surface that is in contact with the first electrode 102. In other words, d1 is shorter than d3 in FIG. 4. With the above-mentioned structure according to the second embodiment the increase in volume of the resin member 400 can be prevented more than that in the first embodiment, and thereby the increase in amount of thermal expansion of the resin member 400 can be further prevented. As a result, according to the second embodiment, the fracture of the connection portion between the first electrode 102/the second electrode 202 and the connection member 300 can be further prevented.

Similarly to the first embodiment, the electronic component 500 according the second embodiment can obtain an advantageous effect, which is similar to that obtained between the second electrodes 202 (the D region in FIG. 2B), also between the second electrode 202 and the first substrate 101 (the E region in FIGS. 2A and 2C).

The electronic component 500 having the structure exemplified in FIG. 4 can be manufactured, by the manufacturing method for manufacturing the electronic component 500 according to the first embodiment, by addition of pressure at the time of pressing and heating, increase of a temperature at the time of pressing and heating, or by change of hardness of the second structure 200.

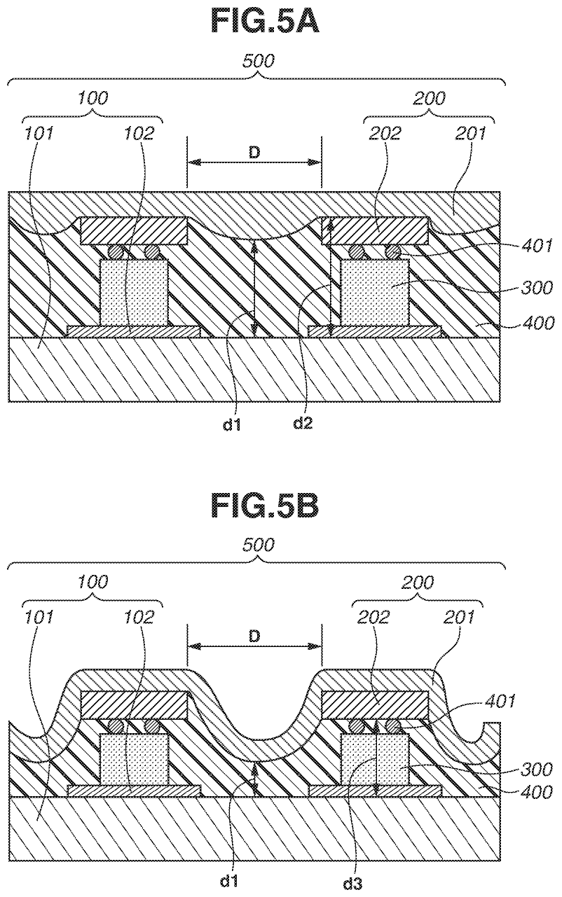

An electronic component 500 according to the third embodiment is to be described with reference to FIGS. 5A and 5B.

The third embodiment illustrated in FIGS. 5A and 5B is different from the first embodiment illustrated in FIG. 2B and the second embodiment illustrated in FIG. 4, respectively, in that conductive particles 401 are arranged between the second electrode 202 and the connection member 300. FIGS. 5A and 5B each illustrate the conductive particles 401 as the intermediary body arranged between the second electrode 202 and the connection member 300, but the intermediary body is not specifically limited to the conductive particles as long as a material of the intermediary body is capable of electrically connecting the second electrode 202 and the connection member 300. The conductive particles 401 are arranged between the second electrode 202 and the connection member 300, so that the conductive particles 401 enter into at least one of the second electrode 202 or the connection member 300. As a result, connection force between the second electrode 202 and the connection member 300 increases. Specifically, the conductive particles 401 are arranged so that recessed portions are formed on a surface of at least one of the second electrode 202 or the connection member 300. As a result, it is possible to further prevent the fracture of the connection portion between the second electrode 202 and the connection member 300. FIGS. 5A and 5B each illustrate the conductive particles 401 arranged only between the second electrode 202 and the connection member 300, but the structure is not limited to these examples. The conductive particles 401 may be arranged between the first electrode 102 and the connection member 300, or may be arranged in a portion of the resin member 400 other than a portion between the first electrode 102/the second electrode 202 and the connection member 300.

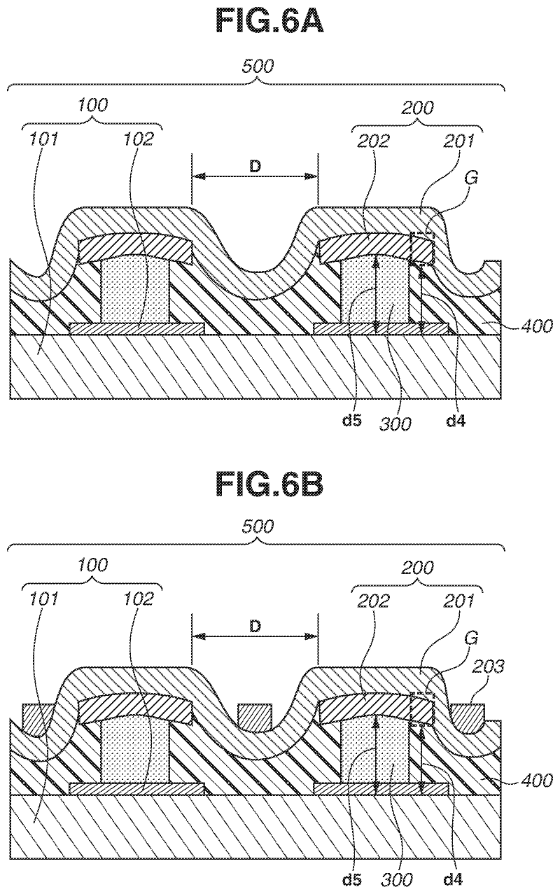

An electronic component 500 according to a fourth embodiment is to be described with reference to FIGS. 6A and 6B.

The fourth embodiment illustrated in FIG. 6A is different from the second embodiment illustrated in FIG. 4 in that the second electrode 202 is curved. In other words, a distance between a portion of the third principal surface that is not in contact with the connection member 300 (G region in FIG. 6A) and the first principal surface (d4 in FIG. 6A) is shorter than a distance between a portion of the third principal surface that is in contact with the connection member 300 and the first principal surface (d5 in FIG. 6A). With the above-mentioned structure, it is possible to further prevent the increase in volume of the resin member 400 arranged between the first substrate 101 and the second substrate 201 in comparison with a state where the second electrode 202 is not curved. Consequently, it is possible to further prevent the fracture of the connection portion between the second electrode 202 and the connection member 300.

The electronic component 500 illustrated in FIG. 6B has a structure in which an external electrode 203 is arranged on the second substrate 201, in addition to the structure illustrated in FIG. 6A. Particularly, the external electrode 203 is arranged on the second substrate 201 in a region that is not in contact with the second electrode 202 (D region in FIG. 6B), so that the distance between the portion of the first principal surface that is not in contact with the first electrode 102 and the portion of the second principal surface that is not in contact with the second electrode 202 can be further shortened. Hence, it is possible to further prevent the increase in volume of the resin member 400 arranged between the first substrate 101 and the second substrate 201 in comparison with the structure illustrated in FIG. 6A. Consequently, it is possible to further prevent the fracture of the connection portion between the second electrode 202 and the connection member 300.

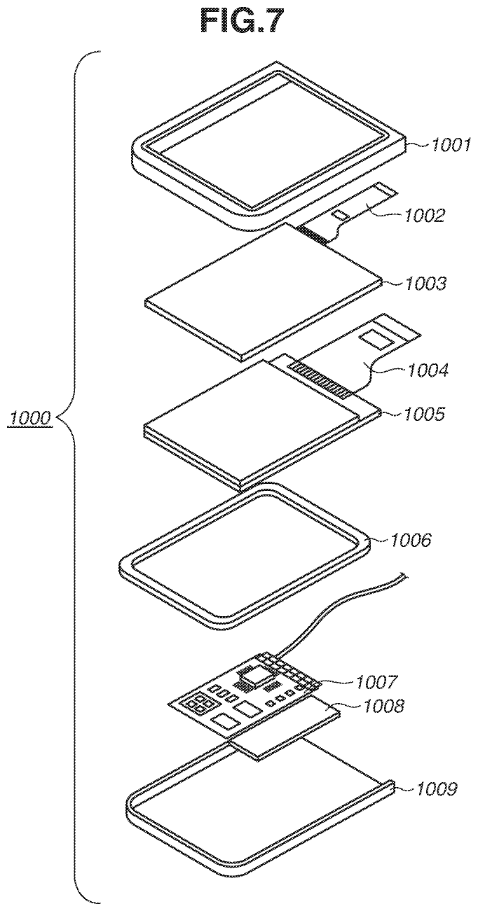

Application examples are now to be described. FIG. 7 is a schematic diagram illustrating an example of a display apparatus according to an embodiment of the present disclosure. A display apparatus 1000 may include a touch panel 1003, a display panel 1005, a frame 1006, a circuit substrate 1007, and a battery 1008 between an upper cover 1001 and a lower cover 1009. Flexible print circuits FPC 1002 and 1004 are connected to the touch panel 1003 and the display panel 1005, respectively. The touch panel 1003 and the display panel 1005 correspond to the first substrate 101 on the first principal surface of which the first electrode 102 is arranged, and the flexible print circuits FPC 1002 and 1004 each correspond to the second substrate 201 on the second principal surface of which the second electrode 202 is arranged.

Transistors are printed on the circuit substrate 1007. The battery 1008 may not be arranged unless the display apparatus is a mobile device. Even if the display apparatus is the mobile device, the battery 1008 may be arranged at another position.

The display apparatus according to the present embodiment may have a color filter colored in red, green, and blue. In the color filter, red, green, and blue may be arranged in a delta array.

The display apparatus according to the present embodiment may be used for a display unit of an imaging apparatus including an image pickup element that receives light. The imaging apparatus may further include an optical unit having a lens, and the image pickup element may receive light that passes through the optical unit. A single lens or a plurality of lenses may be included in the optical unit. The imaging apparatus may include a display unit that displays information acquired by the image pickup element. The display unit may be a display unit that is exposed to the outside of the imaging apparatus, or a display unit that is arranged in a viewfinder. The imaging apparatus may be a digital camera or a digital video camera.

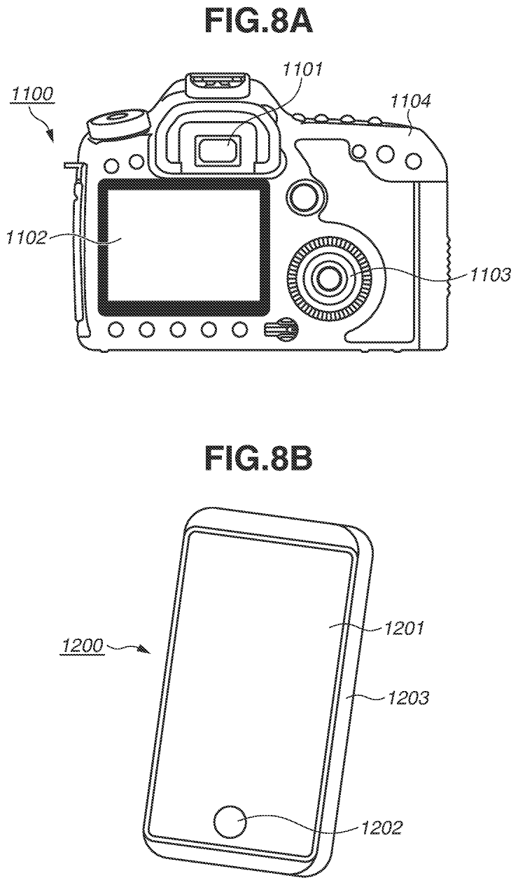

FIG. 8A is a schematic diagram illustrating an example of the imaging apparatus according to an embodiment of the present disclosure. An imaging apparatus 1100 may include a viewfinder 1101, a rear surface display 1102, an operation unit 1103, and a housing 1104. The viewfinder 1101 and the rear surface display 1102 may include the electronic component according to the present disclosure. In this case, the display apparatus may display not only a captured image, but also environment information, an imaging instruction, and the like. The environment information may be information regarding an intensity of external light, a direction of external light, a moving speed of an object, a possibility that the object is blocked by an obstacle, or the like.

The imaging apparatus 1100 includes an optical unit, which is not illustrated. When the optical unit includes a plurality of lenses, light that passes through the optical unit is formed as an image on an image pickup element housed in the housing 1104. Relative positions of the plurality of lenses are adjusted so that a focal point can be adjusted. This operation may be manually or automatically performed. The imaging apparatus may be referred to also as a photoelectric conversion apparatus.

The photoelectric conversion apparatus is capable of performing, instead of performing sequential imaging, a method of detecting a difference from a previous image, a method of cutting out an image from constantly recorded images, or the like as an imaging method.

FIG. 8B is a schematic diagram illustrating an example of an electronic apparatus according to an embodiment of the present disclosure. An electronic apparatus 1200 includes a display unit 1201, an operation unit 1202, and a housing 1203. The housing 1203 may include a circuit, a print substrate including the circuit, a battery, and a communication unit. The operation unit 1202 may be a button or a touch panel-type reaction unit. The operation unit 1202 may be a biometrics unit that performs recognition of a fingerprint to unlock a lock, and the like. The electronic apparatus including the communication unit can be referred to also as a communication apparatus. The electronic apparatus may include a lens and an image pickup element to further have a camera function. Pixels with which imaging is performed with the camera function are displayed on the display unit 1201. Examples of the electronic apparatus include a smartphone, and a laptop computer.

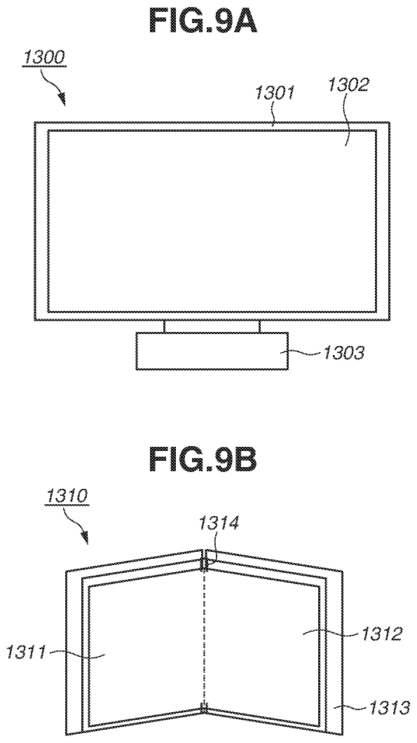

FIGS. 9A and 9B are schematic diagrams each illustrating an example of a display apparatus according to an embodiment of the present disclosure. FIG. 9A illustrates the display apparatus such as a television monitor and a personal computer (PC) monitor. A display apparatus 1300 includes a housing 1301 and a display unit 1302. The electronic component according to the present disclosure may be used for the display unit 1302. The display apparatus 1300 may further include a base 1303 that supports the housing 1301 and the display unit 1302. The base 1303 is not limited to a mode illustrated in FIG. 9A. A lower side of the housing 1301 may serve also as a base. The housing 1301 and the display unit 1302 may be curved.

A curvature radius of the curve may be 5000 mm or more and 6000 mm or less.

FIG. 9B is a schematic diagram illustrating another example of the display apparatus according to the present embodiment. A display apparatus 1310 illustrated in FIG. 9B is configured to be bendable, and is a so-called foldable display apparatus. The display apparatus 1310 includes a first display unit 1311, a second display unit 1312, a housing 1313, and a folding point 1314. The first display unit 1311 and the second display unit 1312 may include the electronic component according to the present disclosure. The first display unit 1311 and the second display unit 1312 may be one seamless sheet of the display apparatus. The first display unit 1311 and the second display unit 1312 can be divided at the folding point 1314. The first display unit 1311 and the second display unit 1312 may display mutually different images, or may display one image.

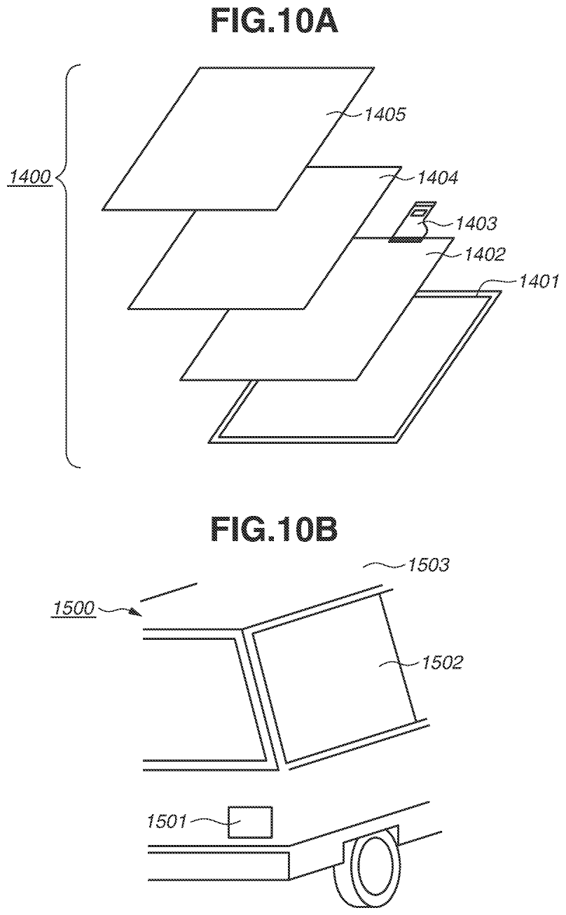

FIG. 10A is a schematic diagram illustrating an example of an illumination apparatus according to an embodiment of the present disclosure. An illumination apparatus 1400 may include a housing 1401, a light source 1402, and a circuit substrate 1403. The light source 1402 corresponds to the first substrate 101 on the first principal surface on which the first electrode 102 is arranged, and the circuit substrate 1403 corresponds to the second substrate 201 on the second principal surface on which the second electrode 202 is arranged. The illumination apparatus 1400 may include an optical film 1404 to enhance color rendering properties of a light source. The illumination apparatus 1400 may include a light diffusion unit 1405 to effectively diffuse light of the light source. The illumination apparatus 1400 includes the light diffusion unit 1405, and can thereby deliver light to a wide range. The optical film 1404 and the light diffusion unit 1405 may be arranged on an emission side of illumination light. A cover may be arranged on the outermost part as necessary.

The illumination apparatus is, for example, an apparatus that illuminates the inside of a room. The illumination apparatus may be an apparatus that emits light in colors of any of white, daylight white, and other colors from blue to red. The illumination apparatus may include a light modulating circuit that modulates light in these colors. The illumination apparatus may include a power source circuit. The power source circuit may be a circuit that converts an alternating voltage to a direct voltage. White has a color temperature of 4200 K, and daylight white has a color temperature of 5000 K. The illumination apparatus may include a color filter.

The illumination apparatus according to the present embodiment may include a heat dissipation unit. The heat dissipation unit dissipates heat inside the illumination apparatus to the outside of the illumination apparatus. Examples of a material of the heat dissipation unit include a metal with higher specific heat and liquid silicon.

FIG. 10B is a schematic diagram illustrating an automobile as an example of a moving object according to an embodiment of the present disclosure. The automobile includes a tail lamp, which is an example of a lighting fixture. An automobile 1500 includes a tail lamp 1501, and the tail lamp 1501 may be turned on when a braking operation or the like is performed. The automobile 1500 may include an automobile body 1503 and a window 1502 fixed to the automobile body 1503.

The tail lamp 1501 may include the electronic component according to the present disclosure. The tail lamp 1501 may include a protective member that protects a light source. A material of the protective member is not specifically limited as long as having high strength to some extent and having transparency, but the protective member is preferably made of polycarbonate or the like. A furandicarboxylic acid derivative, an acrylonitrile derivative, or the like may be mixed with polycarbonate.

The moving object according to the present embodiment may be an automobile, a ship, an airplane, a drone, or the like. The moving object may include a body and a lighting fixture mounted on the body. The lighting fixture may emit light so that a position of the body is notified.

The electronic apparatus or the display apparatus can be applied to, for example, a system that can be mounted as a wearable device such as smart glasses, a head-mounted display, and a smart contact lens. The electronic apparatus may include an imaging apparatus that is capable of photoelectrically converting visible light, and a display apparatus that is capable of emitting visible light.

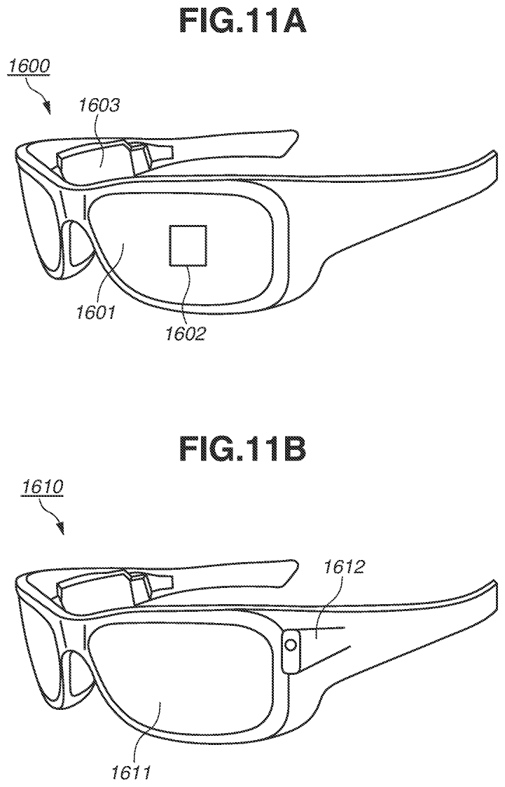

FIGS. 11A and 11B are schematic diagrams each illustrating an example of glasses (smart glasses) according to an embodiment of the present disclosure. Glasses 1600 (smart glasses) are to be described with reference to FIG. 11A. The glasses 1600 include a display unit on a rear surface of a lens 1601. The display unit may include the electronic component according to the present disclosure. Furthermore, an imaging apparatus 1602 such as a complementary metal-oxide semiconductor (CMOS) sensor and a single photon avalanche diode (SPAD) sensor may be arranged on a front surface of the lens 1601.

The glasses 1600 further include a control apparatus 1603. The control apparatus 1603 functions as a power source that supplies power to the imaging apparatus 1602 and the display unit. The control apparatus 1603 controls operations of the imaging apparatus 1602 and the display unit. An optical system for condensing light into the imaging apparatus 1602 or the display unit is formed in the lens 1601.

Glasses 1610 (smart glasses) are to be described with reference to FIG. 11B. The glasses 1610 include a control apparatus 1612, on which the display apparatus including the electronic component according to the present disclosure is arranged. The control apparatus 1612 may further include an imaging apparatus corresponding to the imaging apparatus 1602. An optical system for projecting light emitted from the control apparatus 1612 is formed in a lens 1611, and an image is projected onto the lens 1611. The control apparatus 1612 functions as a power source that supplies power to the imaging apparatus and the display unit, and also controls operations of the imaging apparatus and the display apparatus. The control apparatus 1612 may include a line-of-sight detection unit that detects a line-of-sight of a person with the glasses 1610. The line-of-sight may be detected using infrared light. An infrared light emission unit emits infrared light toward the eyeball of a user who gazes at a display image. An imaging unit including a light receiving element detects reflected light from the eyeball, out of the emitted infrared light, and thereby obtains a captured image of the eyeball. The glasses 1610 include an attenuation unit that attenuates light that is emitted from the infrared light emission unit toward the display unit in a plan view, and thereby degradation of image quality can be prevented.

The control apparatus 1612 detects the line-of-sight of the user with respect to a display image from the image of the eyeball captured with infrared light. A freely selected, publicly known method can be applied to the detection of the line-of-sight using the captured image of the eyeball. As one example, it is possible to use a line-of-sight detection method based on a Purkinje image formed by reflection of irradiation light on a cornea.

More specifically, line-of-sight detection processing based on a pupillary/corneal reflex method is performed. The line-of-sight of the user is detected by production of a line-of-sight vector indicating the orientation of the eyeball (rotation angle) based on a pupil image included in the captured image of the eyeball and the Purkinje image. The display apparatus according to an embodiment of the present disclosure may include the imaging apparatus including the light receiving element, and may control a display image of the display apparatus based on line-of-sight information about the user from the imaging apparatus.

Specifically, the display apparatus determines a first field-of-view region at which the user gazes and a second field-of-view region other than the first field-of-view region based on the line-of-sight information. The first field-of-view region and the second field-of-view region may be determined by a control apparatus of the display apparatus or may be determined by an external control apparatus and received by the display apparatus. In a display region of the display apparatus, the display apparatus may perform control so that a display resolution in the first field-of-view region is higher than a display resolution in the second field-of-view region. That is, the display resolution in the second field-of-view region may be made lower than the display resolution in the first field-of-view region.

Artificial intelligence (AI) may be used to determine the first display region or a display region with higher priority. The AI may be a model that is configured to estimate an angle of the line-of-sight and a distance to a target of the line-of-sight from the image of the eyeball using the image of the eyeball and a direction of the actual gaze of the eyeball as teacher data. The AI may be included in the display apparatus, the imaging apparatus, or an external apparatus. In a case where the external apparatus includes the AI, the present disclosure can be preferably applied to smart glasses further including an imaging apparatus that captures an image of the outside. The smart glasses are capable of displaying outside information as captured images in real time.

As just described, in the electronic component according to the present disclosure, the increase in volume of the resin member arranged between the first substrate and the second substrate can be prevented, and thereby the fracture of the connection portion between the electrode and the connection material can be prevented. It goes without saying that the present disclosure is not limited to the above-mentioned embodiments, and the above-mentioned embodiments can be modified and combined as appropriate without departing from the gist of the present disclosure.

According to the present disclosure, it is possible to prevent the fracture of the connection portion between the connection member and the electrode under a high temperature environment.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of priority from Japanese Patent Application No. 2022-155186, filed Sep. 28, 2022, which is hereby incorporated by reference herein in its entirety.

What is claimed is:

1. An electronic component comprising:
a first electrode;
a second electrode;
a first substrate having a first principal surface;
a second substrate having a second principal surface; and
a connection member configured to connect the first electrode and the second electrode,
wherein the first electrode and the second electrode are arranged on the first principal surface and the second principal surface, respectively,
wherein a height of the connection member in a direction perpendicular to the first principal surface is greater than a height of each of the first electrode and the second electrode in the direction perpendicular to the first principal surface,
wherein a distance between a portion of the first principal surface that is not in contact with the first electrode and a portion of the second principal surface that is not in contact with the second electrode is shorter than a distance between a portion of the first principal surface that is in contact with the first electrode and a portion of the second principal surface that is in contact with the second electrode, and
wherein an intermediary body is arranged between the second electrode and the connection member.

2. The electronic component according to claim 1,
wherein the second electrode has a third principal surface that is in contact with the connection member, and
wherein the distance between the portion of the first principal surface that is not in contact with the first electrode and the portion of the second principal surface that is not in contact with the second electrode is shorter than a distance between the portion of the first principal surface that is in contact with the first electrode and the third principal surface.

3. The electronic component according to claim 1, wherein the intermediary body includes conductive particles.

4. The electronic component according to claim 1, wherein the second electrode is curved.

5. The electronic component according to claim 4,
wherein the second electrode has a third principal surface that is in contact with the connection member, and
wherein a distance between a portion of the third principal surface that is not in contact with the connection member and the portion of the first principal surface that is in contact with the first electrode is shorter than a distance between a portion of the third principal surface that is in contact with the connection member and the portion of the first principal surface that is in contact with the first electrode.

6. The electronic component according to claim 1, wherein the connection member is a stud bump formed by a wire bonding method.

7. An electronic component comprising:
a first electrode;
a second electrode;
a first substrate having a first principal surface;
a second substrate having a second principal surface; and
a connection member configured to connect the first electrode and the second electrode,
wherein the first electrode and the second electrode are arranged on the first principal surface and the second principal surface, respectively,
wherein a height of the connection member in a direction perpendicular to the first principal surface is greater than a height of each of the first electrode and the second electrode in the direction perpendicular to the first principal surface,
wherein a distance between a portion of the first principal surface that is not in contact with the first electrode and a portion of the second principal surface that is not in contact with the second electrode is shorter than a distance between a portion of the first principal surface that is in contact with the first electrode and a portion of the second principal surface that is in contact with the second electrode, and
wherein the second electrode is curved.

8. The electronic component according to claim 7,
wherein the second electrode has a third principal surface that is in contact with the connection member, and
wherein a distance between a portion of the third principal surface that is not in contact with the connection member and the portion of the first principal surface that is in contact with the first electrode is shorter than a distance between a portion of the third principal surface that is in contact with the connection member and the portion of the first principal surface that is in contact with the first electrode.

9. The electronic component according to claim 7, wherein the connection member is a stud bump formed by a wire bonding method.

10. A photoelectric conversion apparatus comprising:
an image pickup element configured to receive light; and
a display unit configured to display an image captured by the image pickup element,
wherein the electronic component according to claim 1 is the display unit.

11. A display apparatus comprising:
a display unit including the electronic component according to claim 1; and
a housing in which the display unit is arranged.

12. An electronic apparatus comprising:
a display unit including the electronic component according to claim 1;
a housing in which the display unit is arranged; and
a communication unit that is arranged in the housing and that is configured to communicate with an external device.

13. An illumination apparatus comprising:
a light source including the electronic component according to claim 1; and
a housing in which the light source is arranged.

14. A moving object comprising:
a lighting fixture including the electronic component according to claim 1; and
a body in which the lighting fixture is arranged.

15. A wearable device comprising:
a display unit including the electronic component according to claim 1;
an optical system configured to condense light into the display unit; and
a control apparatus configured to control operations of the display unit.

16. A photoelectric conversion apparatus comprising:
an image pickup element configured to receive light; and
a display unit configured to display an image captured by the image pickup element,
wherein the electronic component according to claim 7 is the display unit.

17. A display apparatus comprising:
a display unit including the electronic component according to claim 7; and
a housing in which the display unit is arranged.

18. An electronic apparatus comprising:
a display unit including the electronic component according to claim 7;
a housing in which the display unit is arranged; and
a communication unit that is arranged in the housing and that is configured to communicate with an external device.

19. An illumination apparatus comprising:
a light source including the electronic component according to claim 7; and
a housing in which the light source is arranged.

20. A moving object comprising:
a lighting fixture including the electronic component according to claim 7; and
a body in which the lighting fixture is arranged.

21. A wearable device comprising:
a display unit including the electronic component according to claim 7;
an optical system configured to condense light into the display unit; and
a control apparatus configured to control operations of the display unit.

22. A manufacturing method for manufacturing an electronic component, the electronic component comprising:
a first structure including a first substrate having a first principal surface, and a first electrode arranged on the first principal surface;
a second structure including a second substrate having a second principal surface, and a second electrode arranged on the second principal surface; and
a connection member configured to connect the first electrode and the second electrode,
the manufacturing method comprising:
forming the connection member so that the connection member is in contact with the first electrode or the second electrode;
arranging the first structure and the second structure so that the connection member connects the first electrode and the second electrode, after forming the connection member; and
pressing and heating at least one of the first structure or the second structure.
